(19) United States
(12) Patent Application Publication
(10) Pub. No.: US 2008/0198436 A1
(43) Pub. Date: Aug. 21, 2008

(54) Optical device

(76) Inventors: Daniel R. Blakley, Philomath, OR (US); Scott Lerner, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/709,460

(22) Filed: Feb. 21, 2007

(51) Int. Cl. G02B 26/08; H01L 41/22

(52) U.S. Cl. 359/224; 29/25.35

(57) ABSTRACT

Embodiments of an optical device including a capacitively driven flexible membrane are disclosed.

### BACKGROUND

In the application of optical devices, such as reflective optical devices, it may be difficult to selectively reflect imaging light.

### BRIEF DESCRIPTION OF THE DRAWINGS

FIG. 1 is an isometric view of one example embodiment of a reflective optical device.

FIG. 1A is a detailed cross-sectional view of the top membrane of the device of FIG. 1.

FIG. 2 is a cross-sectional side view of one embodiment of an optical device.

FIG. 3 is a top view of one embodiment of an optical device showing four top electrodes of a pixel region.

FIG. 4 is a cross-sectional side view of one embodiment of the pixel region of FIG. 3 in an unactived position.

FIG. 5 is a cross-sectional side view of one embodiment of the pixel region of FIG. 3 in an activated, raised position.

FIG. 6 is a cross-sectional side view of one embodiment of the pixel region of FIG. 3 in an activated, tilted position.

FIG. 7 is a cross-sectional side view of one embodiment of the pixel region of FIG. 3 in an activated, complex tilted position.

### DETAILED DESCRIPTION OF THE DRAWINGS

The present disclosure provides an apparatus, a method of manufacturing, and a method of using an optical device. The optical device can be utilized in a wide variety of applications, such as in adaptive optics, and may include a continuously variable deformable membrane including a distributed capacitive array. The optical system may employ optics to direct light to an adaptive optical device and/or to collect light from an adaptive optic device. For ease of illustration, the disclosure will discuss one embodiment, namely, a microfabricated reflective device.

The device of the present disclosure can be positioned in any orientation and so the terms “up,” “down,” “top,” “bottom,” “above,” “below,” and the like, are used for illustrative purposes only with respect to figures shown herein.

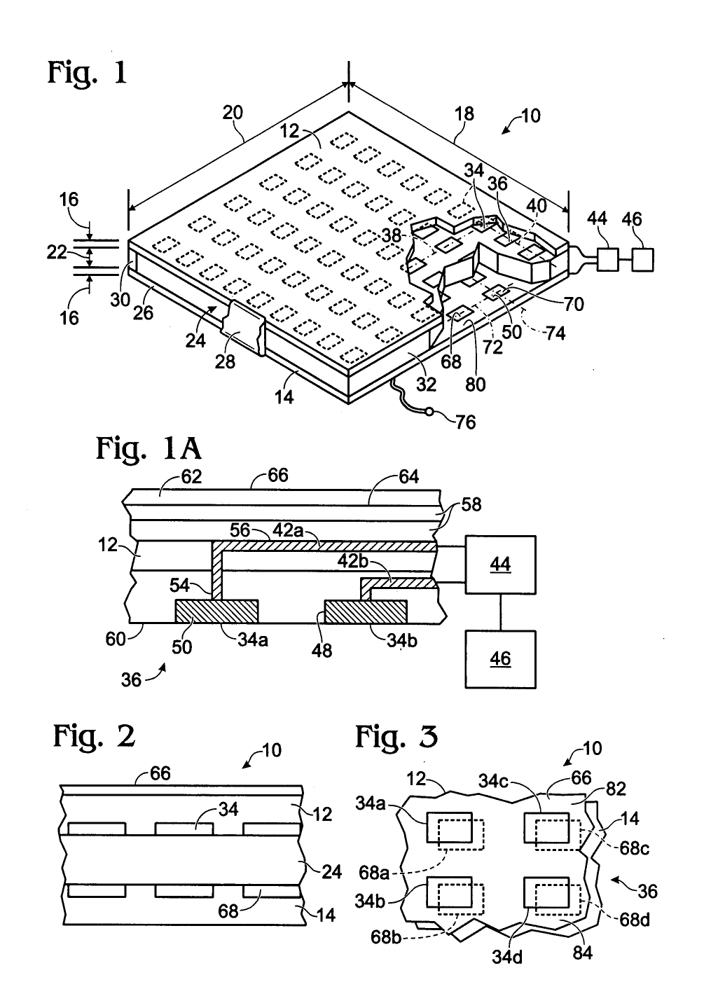

FIG. 1 shows an optical device 10 including a continuously variable deformable membrane 12 positioned above a base 14. Continuously variable deformable membrane 12 may be manufactured of a flexible material, such a silicon, and may be manufactured having a thickness 16, a width 18 and a length 20 sufficient to allow flexibility of membrane 12 in all regions therein. In one embodiment, membrane 12 may have a thickness 16 of approximately ten microns, a width 18 of approximately one inch and length 20 of approximately one inch. However, in other embodiments, any dimensions of device 10 may be utilized. Thickness 16 may be chosen so as to allow deformation or flexing of membrane 12 without breakage of the membrane. Membrane 12 may be manufactured by microfabrication techniques such as sputtering or vapor deposition.

Base 14 may be rigid and may be manufactured of any suitable material such as a semiconductor material, or the like. Base 14 may be spaced from membrane 12 by a distance 22 of approximately twenty microns in the example embodiment shown, so as to form a cavity 24 between base 14 and membrane 12. Base 14 and membrane 12 may be secured around their perimeter 26 by an adhesive 28 (shown in a single corner region of device 10 for ease of illustration), such as an adhesive tape, or the like. A spacer 30 may be utilized to space membrane 12 from base 14 in perimeter region 26.

Cavity 24 may be filled with a dielectric material 32 such as nitrogen gas or the like, or may be a high dielectric gel. Dielectric material 32 may be positioned within cavity 24 before or after sealing of base 14 and membrane 12 together in perimeter region 26. In one embodiment, membrane 12 and base 14 are sealed on three sides in perimeter region 26. Cavity 24 is then filled with dielectric material 32 and the fourth side is then sealed in perimeter region 26 with adhesive 28.

Membrane 12 may include one or more capacitive electrode elements 34. In one embodiment, membrane 12 may include a plurality of capacitive electrode elements 34 that define an electrode array 36. In one example embodiment, membrane 12 may include several thousand electrode elements 34 (a few are shown in this figure for ease of illustration) which may each have a thickness of approximately a few microns (as measured parallel to thickness 16 of membrane 12). In the example embodiment shown, each of electrode elements 34 of array 36 is arranged in a regular pattern defining evenly spaced rows 38 and columns 40.

Referring to FIG. 1A, each of individual capacitive electrode elements 34 may be individually actuated or addressed by its own electrical connection 42. For example, individual capacitive electrode elements 34a and 34b are each electrically connected to an isolated electrical connection 42a and 42b, respectively.

Each of the electrical connections or leads 42 may be connected to a current source 44 and a controller 46. The controller 46 may address each of the individual capacitive electrode elements 34 with a serial data stream that may demultiplex the array. However, any control method may be utilized to activate each of electrode elements 34.

Each of electrode elements 34 may be formed on flexible membrane 12 by microfabrication techniques. In one example method of manufacture, flexible membrane 12 may be manufactured as a continuous, flexible membrane by deposition techniques. Thereafter, membrane 12 may be etched in selective regions, using a mask (not shown), to define a pattern of depressions 48 (see FIG. 1A) corresponding to the pattern of array 36. A conductive material 50, such as aluminum, silver, gold, indium-tin-oxide, or the like, may then be selectively deposited with the use of a mask (not shown) so as to form conductive regions 34 within depressions 48, wherein each conductive region may define an electrode element 34 of array 36. Thereafter, electrical connections 42 may be manufactured as vias 54 and channels 56 extending though different layers 58 of microfabricated membrane 12.

In the embodiment shown, electrode elements 34 may be positioned on a bottom side 60 of membrane 12. In such an embodiment, a reflective material 62, such as aluminum with a coating of aluminum oxide thereon, may be positioned on a topside 64 of membrane 12. Reflective material 62 may be deposited by microfabrication techniques, such as deposition techniques, to form a thin, continuously variable deformable reflective surface 66 of membrane 12.

Referring again to FIG. 1, and similar to flexible membrane 12, base 14 may include one or more capacitive electrode elements 68. In one embodiment, base 14 may include a plurality of capacitive electrode elements 68 that define an electrode array 70. In the example embodiment shown, each of electrode elements 68 of array 70 is arranged in a regular pattern defining evenly spaced rows 72 and columns 74 that may correspond to the pattern of rows 38 and columns 40 of flexible membrane 12. Electrode elements 68 may be sized slightly differently than the size of electrode elements 34 of membrane 12, so as to reduce fringing effects within device 10. Each of individual capacitive electrode elements 68 may be individually actuated or addressed by its own electrical connection 76 (similar to the connection 42 of membrane 12). Each of the electrical connections or leads 76 may be connected to current source 44 and controller 46.

In one embodiment, flexible membrane 12 and base 14 may define thousands of electrode pairs, which may be referred to as actuators, that may define a quasi-continuous optical wavefront profile. Because the optical surface is continuous, the throughput efficiency of the disclosed device may not depend on the number of actuators. In contrast, the throughput efficiency for a non-continuous optical surface, which may include dead space between elements, may depend on the number of elements utilized.

Base 14 may be formed as a rigid base by any applicable technique. Thereafter, a conductive material 50, such as aluminum, silver, gold or the like, may then be selectively deposited with the use of a mask (not shown) directly on a top surface 80 of base 14 so as to form conductive regions 68, wherein each conductive region may define an electrode element 68 of array 70. Thereafter, electrical connections 76 may be manufactured as wires individually connected to each of electrode elements 68.

FIG. 2 shows a cross-sectional side view of device 10 showing cavity 24 positioned between flexible membrane 12 and base 14.

FIG. 3 shows a top view of a region 82 of device 10 including four electrode elements 34a, 34b, 34c and 34d, of array 36 on flexible membrane 12. In one embodiment of device 10, all of electrode elements 34 of membrane 12 may be divided into groups of four elements, wherein each electrode element 34 of the group of four, such as electrode elements 34a, 34b, 34c and 34d, may be defined a quadrant of a single upper electrode of a pixel 84 of device 10. Similarly, four electrode elements 68a, 68b, 68c and 68d, of base 14 (shown slightly offset for ease of illustration), positioned directly below electrode elements 34a, 34b, 34c and 34d, respectively, may be defined as the quadrants of a single lower electrode of a capacitive electrode pair 86 of pixel 84 of device 10.

As will be described now in more detail, application of a capacitive driving force to each of the quadrant pairs 34a-68a, 34b-68b, 34c-68c and 34d-68d, of pixel 84 will result in movement of flexible membrane 12 in the region of pixel 84, with respect to base 14, such that reflective surface 66 of membrane 12 in the region of pixel 84 will be moved to a desired position so as to reflect light in a desired manner. The desired position of pixel 84 may be a z-axis movement of reflective surface 66 with respect to base 14 or may be a tilted movement of reflective surface 66 with respect to base 14. Accordingly, activation of quadrants of the electrode pair 34-68 of a pixel 84 provides a continuously deformable reflective optical element that is capable of near instantaneous adjustment of the focus, optical axis and focal length of optical device 10. More particularly, each electrode pair 34-68 of array 36 may be sensed and driven capacitively to form a wide variety of reflective optical sub-surfaces or pixel regions 84 within reflective surface 66.

Each of electrode pairs 34-68 functions as a physical displacement drive element as well as a distance measurement transducer. The displacement of each capacitor electrode pair 34-68 is based upon electrostatic attraction and repulsion forces, which is dependent upon the polarity of the voltages applied to each electrode of electrode pair 34-68. To sense a position, i.e., a spacing, of the electrodes 34 and 68 of the pair, a known current/frequency is applied to each electrode 34 and 68. Because the dielectric qualities of dielectric material 32 within cavity 24 is known, and the surface area of the electrode regions 34 and 68 are known, the capacitance can be measured. The capacitance value of the electrode pair 34-68 is inversely proportional to the distance 22 between electrodes 34 and 68, also known as the transducers displacement position. Accordingly, the distance 22 between electrodes 34 and 68 can be calculated from the capacitance value. Once the position of electrodes 34-68 with respect to one another is calculated, an appropriately sized slewing voltage may be applied to electrodes 34-68 to move electrodes 34 and 68 into a desired position, i.e., to bring the transducer position into alignment with an intended value. Several example positions of pixel 84 will now be described.

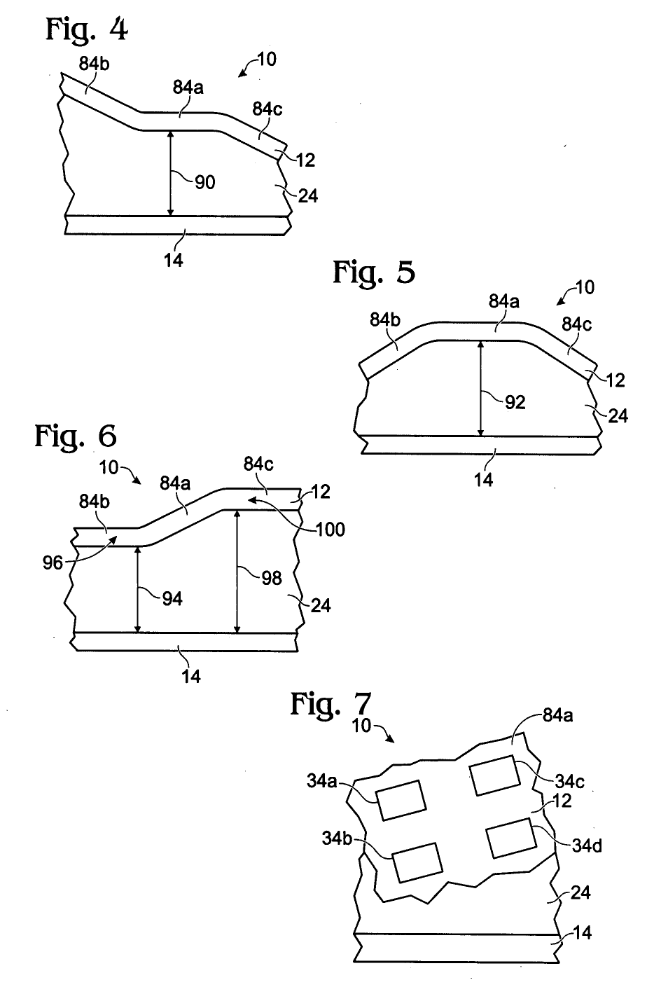

FIG. 4 shows pixel region 84a of device 10 in an unactived position. In this position, membrane 12 and base 14 are spaced a distance 90 of approximately twenty microns and are positioned parallel to one another. As shown, other pixel regions 84b and 84c of flexible membrane 12 may be positioned differently than pixel region 84a.

FIG. 5 shows pixel region 84a of device 10 in an activated, raised position with respect to base 14. In other embodiments, pixel region 84a may be moved to an activated, lowered position with respect to base 14. In this position, membrane 12 and base 14 are spaced a distance 92 of approximately thirty microns, and are positioned parallel to one another. Accordingly, in this raised position a same voltage potential, such as a voltage potential of approximately 10 volts (v), is applied between each of four electrode pairs 34a-68a, 34b-68b, 34c-68c and 34d-68d (see FIG. 3), such that there is an equal capacitive driving force applied at each of the four electrode quadrants 34a-68a, 34b-68b, 34c-68c and 34d-68d of pixel 84, such that each quadrant is raised an equal distance with respect to base 14. In such a raised position, a volume of sealed cavity 24 may be increased, which may be achieved by the use of a dielectric gas material 32, as opposed to a liquid dielectric material, within cavity 24. As shown, other pixel regions 84b and 84c of flexible membrane 12 may be positioned differently than pixel region 84a along continuous flexible membrane 12.

In one example embodiment wherein a 10 volt voltage is applied, the dielectric is in a vacuum, the plates are 20 microns along a length of each side (for a square plate), and the distance is 30 microns between the plates, then the resulting force of attraction, assuming oppositely charged plates, is 393 picoNewtons. In this example embodiment, if such a single electrode pair is one of an array of 1000 by 1000 electrode pairs, then the overall force utilized to move each of the electrode pairs of the array would be 393 microNewtons.

FIG. 6 shows pixel region 84a of device 10 in an activated, tilted position. In this position, membrane 12 and base 14 are spaced a distance 94 of approximately twenty microns in a first end region 96, and are spaced a distance 98 of approximately twenty five microns in a second end region 100. Accordingly, flexible membrane 12 and base 14 are not positioned parallel to one another in the region of pixel 84a. Accordingly, in this tilted position a non-uniform voltage potential may be applied between two sets of the four electrode pairs 34a-68a, 34b-68b, 34c-68c and 34d-68d, such that there is a non-equal capacitive driving force applied at each of the four electrode quadrants of pixel 84, and such that each quadrant is raised an un-equal distance with respect to base 14. For example, a voltage potential of 10 v may be applied to electrode pairs 34a-68a and 34b-68b (see FIG. 3), and a different voltage potential of 12 v may be applied to electrode pairs 34c-68c and 34d-68d (see FIG. 3). In such a tilted position, a volume of sealed cavity 24 may be increased or decreased, which may be achieved by the use of a dielectric gas material 32 within cavity 24. As shown, other pixel regions 84b and 84c of flexible membrane 12 may be positioned differently than pixel region 84a.

FIG. 7 shows pixel region 84a of device 10 in an activated, complex, tilted position. A complex tilted position may be defined as each corner of a pixel region 84a of membrane 12 being spaced a unique distance from base 14. Accordingly, flexible membrane 12 and base 14 are not positioned parallel to one another in the region of pixel 84a. Accordingly, in this complex, tilted position a non-uniform voltage potential may be applied between each of four electrode pairs 34a-68a, 34b-68b, 34c-68c and 34d-68d (see FIG. 3), such that there is a non-equal capacitive driving force applied at each of the four electrode quadrants of pixel 84, and such that each quadrant is raised an un-equal distance with respect to base 14. For example, a voltage potential of 12 v, 10 v, 13v, and 11v may be applied, respectively, at each of four electrode pairs 34a-68a, 34b-68b, 34c-68c and 34d-68d (see FIG. 3). In such a complex, tilted position, a volume of sealed cavity 24 may be increased or decreased which may be achieved by the use of a dielectric gas material 32 within cavity 24.

The optical device 10 as described herein includes the following advantages. The device 10 may be manufactured wholly or partially by microfabrication techniques such as monolithic integrated circuit fabrication techniques or, where large formats may be desired, by silk-screening methods. Such fabrication methods may improve the quality and throughput of the fabrication process and may lower fabrication costs. Even when produced by other methods, the cost of materials for fabricating device 10 may be lower than prior art methods utilizing piezo-electric transducers or magnetically activated electrode pairs.

Due to the ability of reflective surface 66 of device 10 to be moved in a z-axis movement and in a tilting movement, less micro-manipulating steering elements, i.e., less electrode elements 34 and 68, may be utilized to create the desired position of continuously variable reflective surface 66, when compared to prior art devices having a similar resolution. Due to the use of less electrode elements for a similar resolution, the cost of optical device 10 may be less than prior art devices.

The device as described may also provide the ability to compensate for non-uniform shaped projected images. For example, a projector may project an image to a screen positioned non-perpendicular to the projection axis such that the image displayed on the screen may be non-rectangular when optical devices of the prior art may be utilized. However, the continuous flexible membrane optical device as disclosed may allow for compensation of the distorted image by tilting individual pixel regions of the device such that distortions in the final, viewed image are corrected.

Principles of operation of the optical device will now be described. Coulomb's Law for point charges describes the force between two charged particles as F=q₁q₂Rₓ/(4Πer³), where e=8.85×10⁻¹² c²/Nm² for a vacuum, and wherein q₁ and q₂ are the charges on particle 1 and particle 2, respectively, and Rₓ is the distance vector between the particles, which points from one particle to the other. Here q₁ and q₂ are the magnitudes of the charges, Rₓ is a vector which points from one conductive element to its corresponding conductive element, and r is the distance between the conductive elements.

The force between the conductive elements may be attractive when the charges have an opposite electrical sign and may be repulsive when the charges have a like electrical sign. Because Rₓ points from one charge to the other, when the product of the charges is positive, the force one charge exerts on the other is directed away from the one charge and so the other charge is repulsed. When the product of the charges is negative, the force one charge exerts on the other is directed toward the first charge and they are attracted. Accordingly, even in this fundamental example, it is shown that charges may either attract or repulse one another through their inherent electrostatic force field.

The above law may be rewritten in its scaler form as F=q₁q₂/(4Πεₒr²) with the understanding that the force is attractive or repulsive depending on the principles discussed above.

This force relationship can be extended to charged plates, separated by a dielectric material. Assuming a uniform charge distribution in a fermi sea where surface charge density is a function of the overall charge Q and the area of the plates, as follows: =Q/a, so the electric field between the plates is: E=/2εₒ=Q/2Aεₒ, assuming a vacuum with a dielectric constant εₒ, for infinite plates. The potential difference V may be expressed as: V=E/d=dQ/Aεₒ. For oppositely charged plates, the attractive force between the plates is equal to the electric field produced by one plate multiplied by the charge on the other plate: F=QQ/2Aεₒ=εₒAv²/2d². Accounting for the finite dimension of a real set of plates gives: F=(εₒAv²/2d²)(1+2d/D), where D is the diameter of each plate pair and d is the distance between the plates. Specifying an arbitrary dielectric constant ε gives: F=(εAv²/2d²)(1+2d/D). In this equation F is the force in Newtons, A is the area of the deflection electrodes, V is the voltage, D is the diameter of the electrode, and d is the distance between the plates. This is the force of a single actuator, i.e., the force of a single pair of electrode plates. The total force on the membrane is a sum of all individual forces and gives: Pressure=total force/total area.

The adaptive optical capacitive deflection membrane array may include an electrode on the substrate which is electrically isolated from the electrode on the flexible membrane, which may be referred to as an isolated reflective membrane embodiment. In another embodiment, the electrode on the substrate may be electrically connected to the electrode on the flexible membrane, which may be referred to as an integral or common electrode embodiment. In both embodiments, electrode pair fringing fields are enhanced while adjacent electrode fringing fields are reduced to prevent cross-talk.

The individual elements of the common electrode embodiment may be driven individually using the common electrode. The individual elements of the isolated reflective membrane embodiment may be driven differentially. Each embodiment has its own advantages. In the embodiment of the individually driven array, common electrode embodiment, the array may be manufactured with a density which may be greater than a differentially driven array. In other words, more elements may be included within the array of the common electrode embodiment, when compared to the differentially driven embodiment utilizing the same footprint, due to a reduced number of electrical connections being utilized between individual elements. In the embodiment of the differentially driven array, there is a potential for a four fold increase in deflection distance when compared to the common electrode embodiment because the deflection distance is directly related to the deflection force applied. In the differentially driven array embodiment, each electrode may be driven individually, i.e., each electrode of a pair may experience an applied voltage, compared to a single driven electrode in the common electrode embodiment. Force is related to the square of the voltage applied such that a doubling of the voltage applied results in a quadrupling of the force available for deflection.

In another embodiment the adaptive optical array elements may be configured as an x-y matrix such that a standard 44 pin package may be capable of 22 by 22 elements for a total of 484 elements using conventional passive techniques. The density of such embodiments may further be enhanced by using active semiconductor multiplexing techniques such as serially encoded parallel control methods. A drawback to such as method may be that the active components place a further constraint on the breakdown voltage, accordingly to their ratings. However, such a disadvantage may be reduced by limiting the maximum element deflection force in favor of having a higher density of force elements.

The device may also compensate for irregularities and/or non-uniformity of a glass lens system of a projection system, or may correct for eye curvature and irregularities during laser eye surgery.

The device may also provide the ability to compensate for variations in the atmosphere when the device is utilized in astronomy applications.

Other variations and modifications of the concepts described herein may be utilized and fall within the scope of the claims below.

1. An optical device, comprising:
a deformable membrane including a first capacitor electrode array;
a base including a second capacitor electrode array, said base spaced from said deformable membrane to define a cavity therebetween;
a dielectric material positioned within said cavity; and
a reflective surface positioned on said deformable membrane opposite said base, said reflective surface capable of reflecting light through external reflection that is external from said cavity.

2. The device of claim 1 wherein said first capacitor electrode array and said second capacitor electrode array each comprise a plurality of capacitor electrodes that are each individually actuated.

3. The device of claim 1 wherein in a nominal condition said deformable membrane is positioned in an unactivated plane that is positioned parallel to a plane of said base.

4. The device of claim 1 wherein said deformable membrane is a continuous flexible membrane extending across a footprint of said base, and wherein in an activated condition regions of said deformable membrane are moved from said unactivated plane.

5. The device of claim 1 wherein said deformable membrane is manufactured of silicon.

6. The device of claim 2 wherein said plurality of capacitor electrodes of said first capacitor electrode array comprise a conductive material deposited on said deformable membrane.

7. The device of claim 6 wherein said conductive material is chosen from at least one of aluminum, silver, gold, and indium-tin-oxide.

8. (canceled)

9. The device of claim 1 wherein said first electrode array comprises a plurality of electrically isolated conductive regions and said second electrode array comprises a plurality of electrically isolated conductive regions corresponding to said conductive regions of said first electrode array so as to define a plurality of capacitive electrode pairs.

10. The device of claim 9 wherein regions of said deformable membrane are moved with respect to said base by capacitive forces applied between ones of said electrode pairs.

11. The device of claim 9 wherein four adjacent capacitive electrode pairs define a pixel.

12. The device of claim 11 wherein application of a same capacitive force to each of said four adjacent capacitive electrode pairs moves a corresponding pixel region of said deformable membrane in a direction perpendicular to said base, and wherein application of a same capacitive force to less than each of said four adjacent capacitive electrode pairs moves said corresponding pixel region of said deformable membrane in a tilting direction with respect to said base.

13. The device of claim 1 wherein said first capacitor electrode array and said second capacitor electrode array together define a plurality of electrode pairs, wherein said electrode pairs function as physical displacement drive elements and as distance measurement transducers.

14. A method of using an optical device, comprising:
applying a first current to a first capacitive electrode positioned on a continuous, flexible membrane;
applying a second current to a second capacitive electrode positioned on a base separated from said flexible membrane by a dielectric material; and
projecting light to an external reflective surface of said flexible membrane, wherein said external reflective surface of said flexible membrane externally reflects said light to one of an imaging region and a non-imaging region.

15. The method of claim 14 wherein said first current and said second current define a capacitive force between said first electrode and said second electrode that moves said continuous, flexible membrane to a position with respect to said base that corresponds to said first and second currents.

16. The method of claim 14 further comprising applying current to each of a plurality of first capacitive electrodes of an electrode array positioned on said continuous, flexible membrane; and
applying current to a plurality of second capacitive electrodes of an electrode array positioned on said base so as to move different regions of said continuous, flexible membrane into desired positions.

17. The method of claim 16 further comprising projecting said light to said reflective surface of said continuous, flexible membrane, wherein regions of said continuous, flexible membrane that are in an imaging position will reflect said projected light to said imaging region, and wherein regions of said continuous, flexible membrane that are in a non-imaging position will reflect said projected light to a said non-imaging region.

18. A method of making an optical device, comprising:
manufacturing a flexible membrane having a reflective surface;
positioning a plurality of capacitor electrodes on said flexible membrane;
manufacturing a base having a plurality of capacitor electrodes;
positioning said flexible membrane a distance from said base with an absence of spacers positioned between said flexible membrane and said base in a reflection region of said flexible membrane; and
placing a dielectric material between said base and said flexible membrane.

19. The method of claim 18 wherein said positioning said flexible membrane comprises positioning said plurality of electrodes of said flexible membrane in a position aligned with corresponding ones of said plurality of electrodes of said base so as to define a plurality of capacitor electrode pairs.

20. The method of claim 18 further comprising securing said flexible membrane to said base around a perimeter of said device so as to seal said dielectric material therein.

21. The method of claim 18 further comprising manufacturing a conductive lead to each of said plurality of electrodes of said base, manufacturing a conductive lead to each of said plurality of electrodes of said flexible membrane, and connecting each of said leads to a driving force source and to a controller.

22. The method of claim 18 further comprising driving said flexible membrane into a desired configuration by application of one of a common electrode driving force wherein said common electrode drives each of said plurality of capacitor electrodes and a differential driving force wherein each of said plurality of capacitor electrodes is driven individually.

23. The device of claim 1 wherein said cavity includes an absence of spacers in a reflection region of said deformable membrane.
